(19) United States
(12) Patent Application Publication
(10) Pub. No.: US 2009/0108862 A1
(43) Pub. Date: Apr. 30, 2009

(54) Testing system module

(76) Inventor: Cheng-Chin Ni, Hsin-Chu (TW)

Correspondence Address: Nixon Peabody LLP, 200 Page Mill Road, Suite 200, Palo Alto, CA, 94306, US

(21) Appl. No.: 12/045,711

(22) Filed: Mar. 11, 2008

(30) Foreign Application Priority Data
Oct. 24, 2007 (TW) 096139881

(51) Int. Cl. G01R 31/304

(52) U.S. Cl. 324/761

(57) ABSTRACT

A testing system module for testing printed circuit board (PCB) includes a first robot having a pogo pin for moving to a first testing point of a first surface of the PCB and the pogo pin contacting the first testing point; a second robot having another pogo pin for moving to a second point of a second surface of the PCB and the pogo pin contacting the second testing point; and a source meter for forcing the signals to the pogo pins and sensing the signals from the pogo pins.

### BACKGROUND OF THE INVENTION

(1) Field of the invention

The present invention relates to a testing system module for printed circuit board. More particularly, the present invention relates to a testing system module for testing short circuit, open circuit and extreme low leakage current of printed circuit board.

(2) Prior art

In the manufacturing process of printed circuit board, some electrical defects such as short circuit, open circuit, and leakage current would be caused by outside factors. Moreover, evolutions of printed circuit board are high-density, fine pitch, and multi-layer. Therefore, it would cause more cost wasting if the bad board could not be found in time. Besides the improvement of the control of manufacturing process of printed circuit board, improvement of testing technology of printed circuit board is also a good way for manufacturer to reduce scraped rate and raise quality of produce.

In tradition, the way of testing electricity of printed circuit board comprises that using three equipments to perform, which are dedicated test equipment, universal grid test equipment, and flying probe test equipment.

Regarding to dedicated test equipment, which comprises a fixture, such as a dial of testing electricity of printed circuit board. The fixture is only matched one type of printed circuit board. The other types of printed circuit board aren't tested by this dedicated test equipment. Moreover, the fixture would not be reused. Therefore, it wastes cost very much. Otherwise, leakage current of printed circuit board tested by dedicated test equipment lacks stability. The testing data lacks stability that the testing data are not accuracy and the extreme low leakage current, such as nano-ampere level or lower leakage current, could not be tested by the dedicated test equipment.

Universal grid test equipment has a big-size dial being fixture, and the big-size dial has many grids which has testing point. Thus, varied kinds of printed circuit board could be tested by the universal grid test equipment, and the universal grid test equipment does not need to change the fixture. However, as well as dedicated test equipment, leakage current of printed circuit board tested by dedicated test equipment also lacks stability. Moreover, the testing density of printed circuit board tested by universal grid test equipment has limitation. When the printed circuit board is a high-density board, the high-density board isn't tested by the universal grid test equipment.

Flying probe test equipment which merely has two probes to move on x, y, and z axes and to test any testing point of printed circuit board, therefore, it doesn't need more expensive fixture for testing. However, using flying probe test equipment to test printed circuit board still couldn't test the current range of IC testing level. Therefore, it would affect the efficiency and quality of further testing fabrication when the printed circuit board that current range of IC testing level of printed circuit board aren't tested is used to test IC. In order to solve the problem that extreme low leakage current of printed circuit board aren't tested by flying probe test equipment, in general, the testing process of this portion would be performed by extra-manpower. However, it not only wastes manpower but also adds cost of product.

Therefore, it's needed to find a testing system module which could combine the function of auto-continuingly testing and the function of accurately testing leakage current of printed circuit board. Moreover, extreme low leakage current could be tested automatically, the cost of manpower and time could be saved, and the stability of testing data could be promoted.

### SUMMARY OF THE INVENTION

An object of the present invention is to provide a testing system module for testing short circuit, open circuit and extreme low leakage current of printed circuit board.

Another object of the present invention is to provide a testing system module, which is an automatic system module for testing extreme low leakage current of printed circuit board.

To achieve these objects mentioned above, the present invention provides a measuring system module which is used to measure a printed circuit board, including: a first robot having a pogo pin, wherein the first robot could be moved to a testing point of a first surface of the printed circuit board and the pogo pin could be connected with said first testing point; a second robot having another pogo pin, wherein the second robot could be moved to a testing point of a second surface of the printed circuit board and the pogo pin could be connected with the second testing point; a meter, which is used to enter/receive testing signal to the pogo pins; and a control system, which is used to control the first robot and the second robot to move, and control the meter to provide and receive testing signal; and the testing signal from the meter could be transmitted to the control system for defining and analyzing the testing signal.

Therefore, the electricity of the printed circuit board could be tested accurately, and the un-standard printed circuit boards are picked up in time. The efficiency and quality of the printed circuit board is ensured for following production. The better is that the testing system module of the present invention could be controlled by a controlling system, and the testing system module could be a automatic system thereby the cost of manpower could be saved.

### BRIEF DESCRIPTION OF THE DRAWINGS

FIG. 1 is a diagram of a measuring system module of one embodiment of the present invention.

FIG. 2 is a diagram of a shielding case of the measuring system module of one embodiment of the present invention.

### DETAILED DESCRIPTION OF THE INVENTION

Some embodiments of the invention will now be described in greater detail. Nevertheless, it should be noted that the present invention can be practiced in a wide range of other embodiments besides those explicitly described, and the scope of the present invention is expressly not limited except as specified in the accompanying claims. Note that, the components of the different elements are not shown to scale. Some dimensions of the related components are exaggerated to provide a more clear description and comprehension of the present invention.

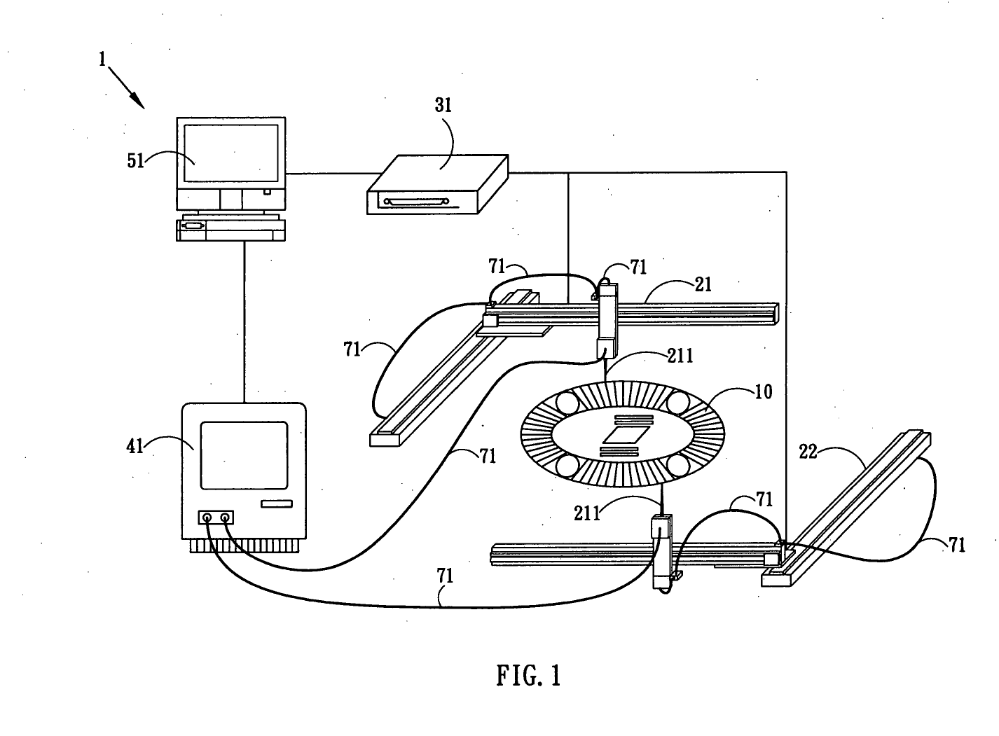

FIG. 1 shows a testing system module 1 of one embodiment of the present invention. The testing system module 1 comprises a testing part and a meter 41. The testing part is one kind of flying test equipment, which comprises a first robot 21 and a second robot 22. In here, the first robot 21 has a pogo pin 211. The printed circuit board 10 comprises a two-side printed circuit board, which has a first surface and a second surface. When testing the printed circuit board 10, the pogo pin 211 of the first robot 21 is contacted with a first testing point of the first surface of printed circuit board 10. The second robot 22 also has a pogo pin 211. Similarly, when testing the printed circuit 10, the pogo pin 211 of the second robot 22 is contacted with a second testing point of the second surface of printed circuit board 10. The purpose of using pogo pin is to avoid the testing point of printed circuit board to be damage. In this embodiment, the first robot 21 and the second robot 22 are xyz orthogonal robots, but do not limit to this. The xyz orthogonal robot is one kind of robot which could be moved along X axis, Y axis, and Z axis that the three axes are perpendicular each other.

The meter 41 is a meter which comprises a test signal generator and a detector. In this embodiment, the meter comprises a source meter, and the source meter could provide an accurately voltage signal and measure extreme low leakage current. The meter 41 is connected with the first robot 21 and the second robot 22 by signal transmission lines 71. Therefore, the electricity, such as short circuit, open circuit and leakage current, of the printed circuit board 10 could be tested by the meter 41 which is used by the pogo pin 211 of the first robot 21 and the pogo pin 211 of the second robot. Moreover, the source meter could measure nano-ampere level leakage current. Furthermore, the signal transmission line 71 covers a metal layer, which is used to avoid the effect of outside electromagnetic interference (EMI).

The testing system module 1 further comprises a control system 51, which is connected with the meter 41, the first robot 21 and the second robot 22. The control system is used to control the meter to provide a voltage to pogo pins of the first robot and the second robot. Moreover, the testing signal tested by meter 41 is received by the control system for defining and analyzing the testing signal. Otherwise, the coordinates of the first robot 21 and the second robot 22 could be controlled by the control system. The testing system module further comprises a movement driver 31, which is disposed between the control system 51 with the first robot 21 and second robot 22. The movement driver 31 could receive the instruction from the control system 51 and drive the first robot 21 and the second robot 22 moving to the testing position.

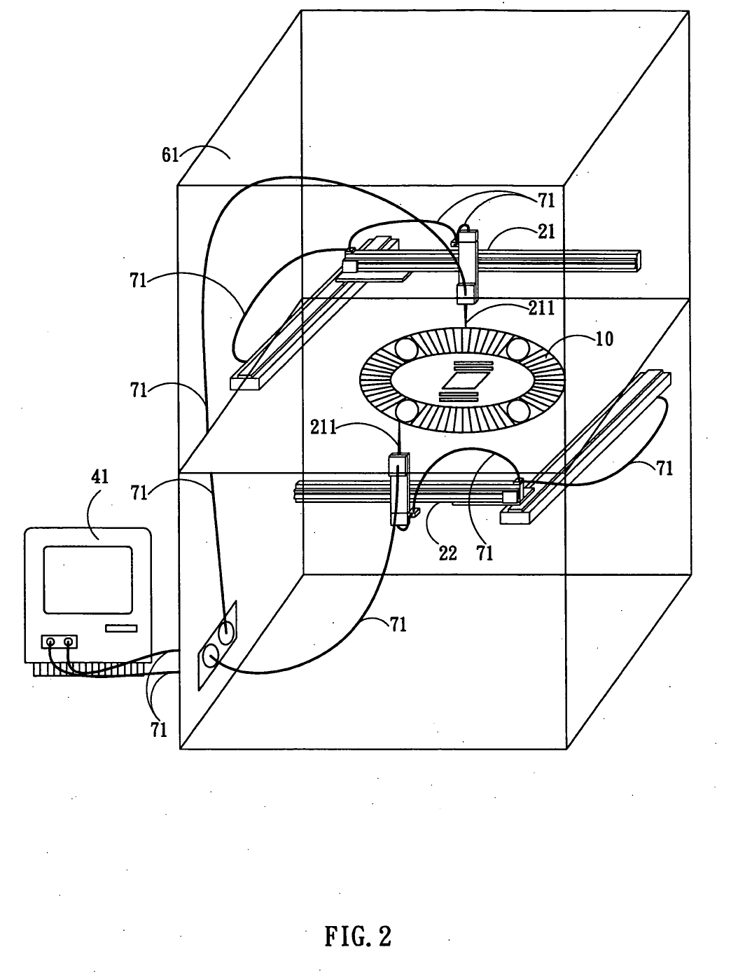

As shown in FIG. 2, the testing system module 1 further comprises a shielding case 61, which is used to cover the testing part to reduce outside electromagnetic interference when the printed circuit board is testing. It's meant that the shielding case 61 covers the first robot 21, the second robot 22 and the printed circuit board 10. The material of shielding case 61 comprises metal, thus, it's efficient to reduce outside electromagnetic interference.

In this embodiment of the present invention, the process that the printed circuit board is tested by the testing system module 1 is described as follow:

First of all, the coordinate of the testing point of the printed circuit board is read by the control system 51. And, the coordinate of the testing point would download automatically by the movement driver, which would control the first robot 21 and the second robot 22 to move along X axis, Y axis, and Z axis that the three axes are perpendicular each other. Moreover, the pogo pin 211 of the first robot 21 could be moved to contact the first testing point of the first surface of the printed circuit board 10, and the pogo pin 211 of the second robot 22 could be moved to contact the second testing point of the second surface of the printed circuit board 10.

Then, the control system 51 is transferred to the meter 41 by transfer protocol. The testing signal from the meter 41 is transferred to the pogo pins of the first robot 21 and the second robot 22, and the pogo pins transfer the voltage to the testing points of the printed circuit board 10 for testing. The testing process comprises short current, open current and leakage current, wherein the leakage current testing could test the extreme low leakage current. Moreover, the testing data could be transferred to the control system 51 by the meter 41, and the testing data of printed circuit board 10 could be defined and analyzed by the control system 51.

Otherwise, two printed circuit boards could be tested at the same time by the testing system module of the present invention. When the one-end testing point of the two printed circuit boards is grounded, the two printed circuit boards could be tested at the same time by the testing system module 1.

Therefore, the testing part of the testing system module of the present invention has the advantage of the flying probe test equipment, and the first robot and the second robot are set on two side of the printed circuit board. When testing the printed circuit board, it only has two probes to move on x, y, and z axes and to test any testing point of printed circuit board. Therefore, it doesn't need more expensive fixture for testing, and extreme high-density printed circuit board could also be tested by the testing system module of the present invention. Otherwise, the testing system module of the present invention comprises a meter 41 would could provide high voltage and receive extreme low current, thus, the testing system module could test nano-ampere level leakage current of the printed circuit board which would be set to high voltage and standard of leakage current is high. Therefore, the electricity of the printed circuit board could be tested accurately, and the un-standard printed circuit board could found in time. The efficiency and quality of the printed circuit board is ensured for following production.

The advantage of the testing system module of the present invention is that the testing system module is an automatic system. Because the meter, the first robot, and the second robot are all connected to the control system, and the voltage and testing data from the meter and the movement of the first and second robots are controlled by the control system. Therefore, it is an automatic system thereby the cost of manpower could be save.

The specific arrangements and methods herein are merely illustrative of the principles of this invention. Numerous modifications in form and detail may be made by those skilled in the art without departing from the true spirit and scope of the invention as defined by claims.

1. A testing system module for testing extreme low leakage current of printed circuit board, including:
a first pogo pin, wherein said first pogo pin is moved by a first robot to a first testing point of said printed circuit board;
a second pogo pin, wherein said second pogo pin is moved by a second robot to a second testing point of said printed circuit board; and
a meter, which is connected electrically with said first pogo pin and said second pogo pin, and comprises a detecting means which is used to enter/receive testing signals to/from said first and second pogo pins, to measure whether leakage current exists in said printed circuit board and display said leakage current, wherein said meter could measure nano-ampere level leakage current.

2. The testing system module of claim 1, wherein said printed circuit board comprises a 2-side printed circuit board.

3. The testing system module of claim 1, wherein two printed circuit boards could be tested at the same time by said testing system module if the one-end testing point of said printed circuit boards is grounded.

4. (canceled)

5. The testing system module of claim 1, wherein said first robot and said second robot are xyz orthogonal robots, which could be moved along X axis, Y axis, and Z axis that the three axes are perpendicular each other.

6. The testing system module of claim 1, wherein further comprises a control system, which is connected with said meter, said first robot and said second robot, and used to control said meter to enter/receive testing signal and said first and second robot to move.

7. The testing system module of claim 1, wherein further comprises a shielding case, which is used to cover said first robot, said second robot, and said printed circuit board to reduce outside electromagnetic interference.

8. A measuring system module which is used to measure a printed circuit board, including:
said printed circuit board, having a first surface and a second surface, and said first surface has a plurality of first testing points and said second surface has a plurality of second testing point;
a first robot having a pogo pin, wherein said first robot could be moved to said testing point of said first surface of said printed circuit board and said pogo pin could be connected with said first testing point;
a second robot having another pogo pin, wherein said second robot could be moved to said testing point of said second surface of said printed circuit board and said pogo pin could be connected with said second testing point;
a meter, which is used to enter/receive testing signal to said pogo pins; and
a control system, which is used to control said first robot and said second robot to move, and control said meter to provide and receive testing signal; and said testing signal from said meter could be transmitted to said control system for defining and analyzing said testing signal.

9. The testing system module of claim 8, wherein said first robot and said second robot are xyz orthogonal robots, which could be moved along X axis, Y axis, and Z axis that the three axes are perpendicular each other.

10. The testing system module of claim 8, wherein further comprises a movement driver, which is used to be connected with said control system, said first robot and said second robot; and said first robot and said second robot is moved by said movement driver which is controlled by said control system.

11. The testing system module of claim 8, wherein further comprises a shielding case, which is used to cover said first robot, said second robot, and said printed circuit board to reduce outside electromagnetic interference.

12. The testing system module of claim 11, wherein material of said shielding case comprises metal.

13. The testing system module of claim 8, wherein further comprises a plurality of signal transmission lines which is used to connect said meter with said pogo pins.

14. The testing system module of claim 13, wherein said signal transmission lines are covered by a metal layer, which is used to avoid outside electromagnetic interference.

15. The testing system module of claim 8, wherein said control system communicates with said meter using a transfer protocol.

16. The testing system module of claim 8, wherein said meter comprises a source meter.

17. A testing system module for testing extreme low leakage current of printed circuit board, comprising:
a flying probe test equipment, having a first pogo pin and a second pogo pin, wherein said first and second pogo pins are used to connect and test said printed circuit board; and
a source meter, which is operatively connected with said first and second pogo pins; and a voltage source for testing said printed circuit board is provided to said first and second pogo pins by said source meter, and leakage current data tested by said first and second pogo pins are received and displayed by said source meter, wherein said source meter could measure nano-ampere level leakage current.

18. The testing system module of claim 17, wherein said flying probe test equipment further comprises a first robot and a second robot, which are connected to said first pogo pin and said second pogo pin respectively.

19. The testing system module of claim 18, wherein said first robot and said second robot are xyz orthogonal robots, which could be moved along X axis, Y axis, and Z axis that the three axes are perpendicular each other.

20. The testing system module of claim 18, wherein further comprises a control system, which is used to be connected with said source meter, said first robot and said second robot; and said first robot and said second robot is moved by a movement driver which is controlled by said control system.

21. The testing system module of claim 20, wherein said control system is transferred to said meter by transfer protocol.

22. The testing system module of claim 17, wherein said printed circuit board comprises a 2-side printed circuit board.

23. The testing system module of claim 17, wherein two printed circuit boards could be tested at the same time by said testing system module if the one-end testing point of said printed circuit boards is grounded.
